(19) United States
(12) Patent Application Publication
(10) Pub. No.: US 2011/0198018 A1
(43) Pub. Date: Aug. 18, 2011

(54) METHOD FOR INTEGRATING AN ELECTRONIC COMPONENT INTO A PRINTED CIRCUIT BOARD

(76) Inventors: Wolfgang Schrittwieser, Kapfenberg (AT); Christria Arzt, Pollau (AT); Klaus Meri, Bruck a. d. Mur (AT)

(21) Appl. No.: 13/125,858

(22) PCT Filed: Oct. 28, 2009
(86) PCT No.: PCT/AT2009/000419

§ 371 Date: Apr. 25, 2011

(30) Foreign Application Priority Data
Oct. 30, 2008 (AT) GM 619/2008

(51) Int. Cl. H05K 3/30

(52) U.S. Cl. 156/150; 156/252; 156/247

(57) ABSTRACT

The invention relates to a method for integrating an electronic component into a printed circuit board, said method comprising the following steps: a layer of a printed circuit board is used to support the electronic component (4); holes (3) corresponding to the contacts (6) of the electronic component (4) are formed in the layer (1); an adhesive (5) is applied to the layer (1) supporting the electronic component (4); the electronic component (4) is fixed to the layer (1) with the contacts (6) oriented towards the layer (1) and the holes (3); adhesive (5) possibly in the region of the holes or perforations (3) is removed, especially by the application of a laser beam (9); and an electroconductive layer (10) is formed for contacting the contacts (6) of the electronic component (4) on the surface of the layer (1), facing away from the component (4). According to said method, in order to remove the adhesive (5) from the holes or perforations (3), a laser beam (9) with dimensions or a diameter measuring more than the internal width of the holes or perforations is used, enabling a simple, rapid and reliable removal of adhesive (5) from the holes (3) corresponding to the contacts (6) of the component (4) to be integrated.

This is a national stage of PCT/AT2009/000419 filed Oct. 28, 2009 and published in German, which has a priority of Austria no. GM 619/2008 filed Oct. 30, 2008, hereby incorporated by reference.

### FIELD OF THE INVENTION

The present invention relates to a method for integrating an electronic component into a printed circuit board, said method comprising the steps of

using or providing a layer of a printed circuit board to support the electronic component;

forming holes or perforations corresponding to the contacts of the electronic component in the layer;

applying an adhesive to the layer supporting the electronic component;

fixing the electronic component to the layer with contacts oriented towards the layer and the holes or perforations;

removing adhesive possibly present in the region of the holes or perforations, especially by the application of a laser beam; and

forming an electroconductive layer for contacting the contacts of the electronic component on the surface or side of the layer facing away from the component.

### PRIOR ART

In the context of growing product functionalities of apparatus provided with electronic components and the increasing miniaturization of such electronic components as well as the increasing number of electronic components to be loaded on printed circuit boards, efficient field-likely or array-likely configured components or packages including several electronic components comprising pluralities of contacts or connections at increasingly reduced distances between said contacts are used to an increasing extent. For fixing or contacting such components, the use of strongly disentangled printed circuit boards is increasingly required, wherein it is to be anticipated that, with the simultaneous reduction of the product sizes as well as the components and circuit boards to be used, it is to be expected, both in terms of the thicknesses and in terms of the surfaces of such elements, that the loading and arrangement of such electronic components via the required plurality of contact pads on printed circuit boards will become problematic, reaching the limits of the possible pattern definition of such contact pads.

To solve these problems, it has meanwhile been proposed to integrate electronic components at least partially into a printed circuit board, wherein a method of the above-mentioned type can, for instance, be taken from WO 2005/125298 or WO 2006/056643. Those known methods aim to provide reliable connections between contacts or contact pads of an electronic component to be integrated and other regions or elements of the component of a printed circuit board to be produced, wherein different methods using, for instance, plasma technology, chemical processes or lasers have been proposed to remove adhesive possibly present in the holes.

However, known methods for integrating electronic components into a printed circuit board frequently involve the drawback of the adhesive contained or present in the region of the holes or perforations having to be removed by a chemical cleaning method. To this end, the partially finished circuit board, with the electronic component fixed to it by an adhesive, is subjected to a substantially all-over treatment in order to remove the adhesive from the region of the holes or perforations for subsequent contacting, wherein such chemical cleaning methods are not only unreliable, particularly because of the usually high filler contents of commercially available adhesive materials, but also do not reliably allow for the complete removal of adhesive from the holes or perforations corresponding to the contacts or contact pads to be contacted, of the electronic component to be integrated. Such chemical cleaning methods operating in a substantially all-over manner, moreover, bear the risk of adhesive being removed not only in the region of the holes or perforations to be cleaned, but also in regions remote from the holes or perforations to be cleaned, due to the fact that such cleaning usually comprises the dipping or immersing of the entire, partially finished circuit board into a bath containing a chemical detergent, so that the reliable fixation of the electronic component to be integrated by the aid of an adhesive will not or only insufficiently be safeguarded. In addition, it is to be anticipated that such electronic components usually comprise extremely large numbers of contacts or contact pads having accordingly small dimensions and mutual distances, so that the introduction of a cleaning solution completely into the holes or perforations to be cleaned, which have accordingly small dimensions, and hence the complete removal of the adhesive contained therein will not be sufficiently ensured merely by dipping into a cleaning solution. As a remedy, an extremely long cleaning period may, for instance, be provided, which will, in the main, result in a deceleration of the production process. Moreover, if complete and reliable cleaning cannot be safeguarded, it is to be anticipated that the contacting in subsequent steps of the contacts or contact pads of the component, which usually have comparatively small dimensions, cannot be properly ensured, thus leading to failures and an increased number of rejects of circuit boards to be produced.

### SUMMARY OF THE INVENTION

The present invention, therefore, aims to avoid the drawbacks of the method of the above-defined kind according to the prior art and, in particular, aims to further develop and improve a method of the initially defined kind to the effect that the reliable removal of the adhesive present in holes or perforations corresponding to the contacts of an electronic component to be integrated and serving to fix the component to a supporting layer will be rapidly achievable by simple means or devices advantageously known per se in the context of the production of a printed circuit board and hence commonly available.

To solve these objects, a method of the initially defined kind is essentially characterized in that, in order to remove the adhesive from the holes or perforations, a laser beam with dimensions or a diameter measuring more than the internal width of the holes or perforations is used. Since the adhesive present in the region of the holes or perforations is removed by a laser beam, the safe and reliable removal of the entire adhesive from the holes or perforations corresponding to the contacts of the component to be integrated has become possible, further advantages of such a removal of the adhesive by the aid of a laser residing in the controllability of such a laser and the uniformity to be achieved during the removal of the adhesive at a simultaneously high process rate. Moreover, it is to be anticipated that the use of lasers in the context of the production of printed circuit boards is widespread anyway, and the use of a laser to remove an adhesive from such holes or perforations in connection with the production of a printed circuit board will thus not call for complex modifications of a production process. The use of a laser is to be considered as an accordingly easily handleable modification of a method for producing a circuit board, such modifications being widespread and, for instance, even required for merely slight changes in the structure or formation of a circuit board. Furthermore, the use of a laser to remove the adhesive present in the holes or perforations will not only provide the respective improvement with a view to reducing the processing time, but, in the context of process controls known for registering a laser beam with such holes or perforations in the production of a circuit board, will also enable and ensure the reliable and complete removal of the adhesive materials present in the holes or perforations. As in contrast to known chemical cleaning procedures, it will, moreover, be safeguarded that only adhesive present in the holes or perforations will be removed, thus eliminating the risk of removing, by the substantially uncontrolled introduction of cleaning solutions, also partial regions of the adhesive that are to ensure the necessary fixation or adherence to the supporting layer, of the electronic component to be integrated. To facilitate the orientation of the laser beam for removing the adhesive from the holes or perforations of the electronic component to be integrated, a laser beam with dimensions or a diameter exceeding the internal width of the holes or perforations is used according to the invention to remove the adhesive from the holes or perforations. By the dimensions or diameter of the laser beam exceeding the internal widths of the holes or perforations, reduced precision in respect to the orientation of the laser beam relative to each one of the holes to be cleaned will, moreover, do. By appropriately selecting the laser as a function of the adhesive materials to be removed, it will at the same time be ensured that materials surrounding the respective hole or perforation, of the layer supporting the electronic component will not be affected by the laser beam, so that respective further improvements of the process rate will also be achievable due to the low demands placed on the precision of aligning or orienting the laser.

For a particularly reliable removal, particularly in consideration of usual components of generally used adhesive materials, it is proposed according to a preferred embodiment of the method according to the invention that the adhesive in the region of the holes or perforations is removed by a CO₂ laser beam. Such a CO₂ laser not only is accordingly easy and reliable to handle and, in parts, widely used in the production of printed circuit boards, but will also ensure that the materials usually contained in adhesives, in particular organic materials, will be reliably removed from the holes or perforations.

Considering the components or compounds usually employed for adhesive materials and/or the filler contents of the same, and in order to achieve accordingly high process speeds while reliably removing the adhesive from the holes or perforations, it is proposed according to a further preferred embodiment that a laser, particularly a pulsed CO₂ laser, having a power of 0.1 to 75 W, particularly 0.1 to 7 W, is used for a period or pulse length of 0.1 to 20 μs, to remove the adhesive from the holes or perforations.

In order to ensure proper embedment of the electronic component to be integrated into the circuit board, and, in particular, also provide a substantially plane surface, which is particularly advantageous and required for the further treatment or processing of a usually multilayer printed circuit board, it is proposed according to a further preferred embodiment that the electronic component, once it has been fixed to the layer, is surrounded by an insulating material, particularly a prepreg and/or a resin, in a manner known per se. Such embedment of the electronic component in an insulating material will accordingly protect said component, with a substantially plane surface being provided to further apply additional circuit board layers or sheets.

Since the circuit board layer that serves to support the electronic component has optionally an extremely small thickness and/or low strength, it is proposed according to a further preferred embodiment that the layer for supporting the electronic component is applied to a carrier layer prior to forming the holes or perforations, which carrier layer is removed prior to removing the adhesive from the holes or perforations. Such a carrier layer provides a sufficiently and accordingly stable base during the application and fixation of the electronic component on the supporting layer. It is, moreover, readily removable after having fixed the electronic component to be integrated and prior to removing the adhesive from the holes or perforations. In order to achieve the necessary strength, such a carrier layer may, for instance, be made of a metal and have an accordingly large thickness, wherein the carrier layer can subsequently be removed or separated in a simple manner and, after this, can optionally be reused in connection with the production of further printed circuit boards.

To subsequently contact in a simple manner the contacts of the electronic component to be integrated, by forming an electrically conducting layer on the surface or side facing away from the component, and to subsequently pattern conductive regions or elements of the circuit board, particularly conductor tracks, it is proposed according to a further preferred embodiment that the layer for supporting the electronic component is formed by a conducting layer.

For a particularly reliable and simple application or formation of the electrically conducting layer for contacting the contacts of the electronic component, it is proposed according to a further preferred embodiment that the electrically conducting layer for contacting the contacts of the electronic component is formed by chemically depositing an electrically conducting or conductive material, particularly copper, or by sputtering a metallic layer. Such chemical depositing or sputtering allows for the formation of a thin and even layer or sheet for contacting, which, in particular, may subsequently serve as a base for applying further, particularly conducting structures, wherein it is additionally proposed in this connection that the electrically conducting layer is applied in a substantially all-over manner on the surface of the supporting layer, that faces away from the component, as in correspondence with a further preferred embodiment of the method according to the invention.

The provision of a substantially plane surface for further forming, in particular, conducting or conductive structures after having contacted the contacts or contact pads of the electronic component to be integrated, it is proposed according to a further preferred embodiment that, after having applied the electrically conducting layer, the holes or perforations are substantially completely filled with a conducting material corresponding to the contacts of the component, particularly by galvanically depositing a conducting material.

To further form or pattern, in particular, conducting or conductive elements or structures of the circuit board to be produced, it is proposed according to a further preferred embodiment that, after the holes have been filled with a conducting material, a substantially all-over layer of a conducting material is applied, particularly by galvanic depositing or plating.

The production of conducting or conductive structures such as conductor tracks is, for instance, feasible in that the layer conducting substantially all over its surface is subsequently subjected to patterning, for instance laser patterning, photo-patterning or the like, as in correspondence with a further preferred embodiment of the method according to the invention.

In order to ensure the removal of heat in an accordingly reliable manner, which is optionally required at a high integration density and compactness of the component to be accommodated, it is, moreover, proposed that a thermally conducting or conductive adhesive is used to fix the component, as in correspondence with a further preferred embodiment of the method according to the invention.

The method according to the invention can, in particular, be employed to produce a multilayer printed circuit board.

### SHORT DESCRIPTION OF THE DRAWINGS

In the following, the invention will be explained in more detail by way of exemplary embodiments schematically illustrated in the accompanying drawing. Therein:

FIGS. 1a to 1f depict different steps of a method according to the invention for producing a printed circuit board having an integrated electronic component; and

FIGS. 2a to 2g depict a modified embodiment of the method according to the invention for producing a printed circuit board, wherein in FIG. 2 only the method steps till removing the adhesive from the holes or perforations of the layer supporting the component are illustrated in detail, while further steps for producing and integrating the component into a particularly multilayer circuit board are apparent from FIG. 1.

### DETAILED DESCRIPTION OF PREFERRED EMBODIMENTS

In all of the Figures, merely a partial region of a circuit board to be produced, i.e. the area of fixation of an electronic component to be integrated into the circuit board is schematically illustrated. In this respect, it is to be anticipated that, in particular, shown thicknesses of individual layers or sheets as well as dimensions of the electronic component and distances of only a small number of contacts or contact sites serving as examples, as well as dimensions of holes or perforations for contacting the contact sites are not to scale.

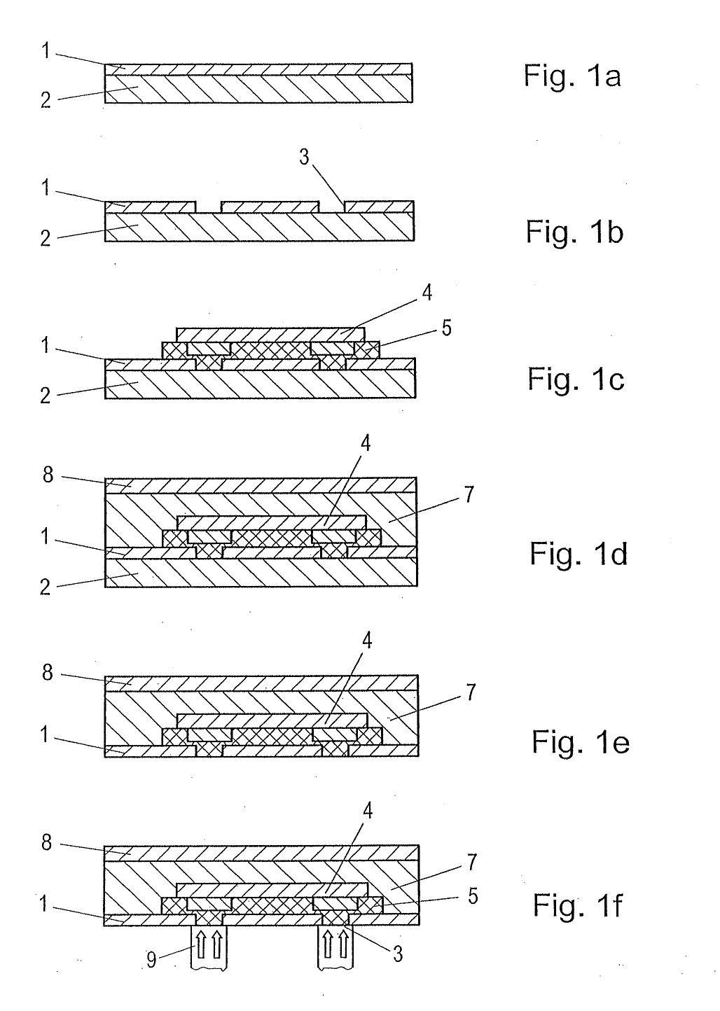

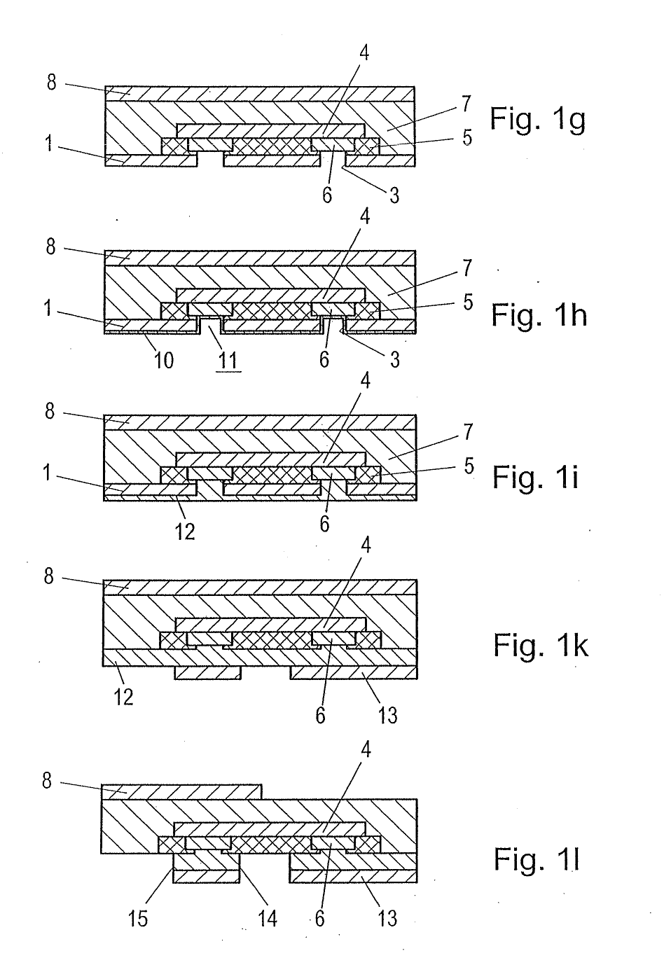

In a first method step according to FIG. 1a, a layer 1 for supporting a subsequently illustrated electronic component to be integrated is provided on a carrier layer denoted by 2.

From FIG. 1b, it is apparent that in a subsequent method step holes or perforations 3 are formed, e.g. by laser drilling or etching, in the layer 1 corresponding to contacts of the electronic component to be subsequently supported on and fixed to the layer 1. For drilling the layer 1, a laser can, for instance, be used, by which the holes or perforations 3 can be rapidly and reliably formed for subsequently contacting contacts of the electronic component to be integrated in the printed circuit board.

In a further method step, according to FIG. 1c, the fixation of an electronic component 4 to the layer 1 is effected by an adhesive indicated by 5. From FIG. 1c, it is moreover apparent that the bores or perforations 3, which are also filled by the adhesive 5, were formed in the layer corresponding to the positions of contacts or contact pads 6 of the component 4, the contacts 6 being oriented to the bores or perforations 3.

In the context of the contacts or contact pads 6 schematically indicated in FIG. 1c, it is noted that such electronic components 4 to be integrated into a circuit board, as a rule, comprise extremely large numbers of contacts or contact pads 6 at distances that are accordingly strongly reduced relative to the graphic presentation.

After having arranged and fixed the electronic component 4 on the layer 1, the electronic component 4 is sheathed or embedded in the step according to FIG. 1d by providing or arranging an insulating material 7, said insulating material 7 being, for instance, formed by a prepreg sheet including a recess adapted to the dimensions of the electronic component 4 to be embedded, or by a layer or sheet 7 of an insulating resin arranged to surround the electronic component 4.

FIG. 1d, in addition, indicates the formation or application of a further layer or sheet, for instance a conducting or conductive layer 8, for the continued construction of a particularly multilayer printed circuit board.

After this, the carrier layer 2 is removed in a further method step, according to FIG. 1e, whereupon the adhesive 5 received or present in the holes or perforations 3 of the layer 1 is removed in a further method step, according to FIG. 1f.

The removal of the adhesive 5 present in the holes or perforations 3 is effected by applying a laser beam, which is schematically indicated by 9 in FIG. 1f.

The laser beam used to remove the adhesive present in the perforations or holes 3 is, for instance, comprised of a CO₂ laser, wherein the following parameters according to Example 1 are used or chosen, in particular, as a function of the materials and/or fillers usually contained in such adhesives 5, to safely and reliably remove the adhesive from the holes or perforations 3.

### Example 1

### Thin Adhesive Layer (15-30 μm) and/or Low Filler Content

Pulsed CO₂ laser
Power: 3 watts
Beam diameter: 180 μm
Pulse duration or length: 6 μs
Number of pulses: 13
Hole diameter: 75 μm

From the illustration according to FIG. 1f, it is moreover apparent that the diameter or dimensions of the laser beam 9 exceed the dimensions of clear widths of the holes or perforations 3 such that, even when meeting low precision demands in orienting the laser beam 9 relative to the holes 3, the adhesive 5 will be safely and reliably removed from the holes or perforations 3 by completely covering the latter.

From the illustration according to FIG. 1f, it is moreover apparent that the directed beam provided by the laser beam 9 will reliably remove the adhesive 5 merely from the holes or perforations 3 without having to fear that, for instance, the uncontrolled penetration or introduction of chemical detergent solutions as used according to the prior art will also cause the removal of adhesive in further partial regions between the layer 1 and the component 4 to be fixed thus affecting or deteriorating the adherence of the component 4 to the layer 1 and/or involving the risk of the occurrence of short-circuits.

In the illustration according to FIG. 1g, the state of the then exposed contacts or contact pads 6 of the electronic component 4 after the removal of the adhesive from the holes or perforations 3 is shown in detail.

Following such a removal of the adhesive from the holes or perforations 3 as illustrated in the steps according to FIGS. 1f and 1g, a further method step comprises the formation or application of an electrically conducting layer 10 for contacting the contacts or contact pads 6 of the electronic component 4 to be integrated. As is apparent from FIG. 1h, the electrically conducting layer 10 for contacting the contacts 6, which has a comparatively small thickness, is formed in a substantially all-over manner on the side or surface of the layer 1 supporting the electronic component, that faces away from the electronic component 4 to be integrated. The electrically conducting layer 10 can, for instance, be applied or formed by chemically depositing an electrically conducting or conductive material, e.g. copper, or by sputtering a metallic layer having an accordingly small layer thickness of, for instance, less than 1 μm.

To continue the construction of a particularly multilayer printed circuit board, the method step following the formation of the electrically conducting layer 10, which is illustrated in FIG. 1h, comprises the filling of the open spaces of the holes or perforations 3, which are indicated by 11 in FIG. 1h, corresponding to the contacts or contact pads 6 of the electronic component 4 to be integrated, likewise with a conducting or conductive material, e.g. copper, the method step according to FIG. 1i, moreover, indicating that a conducting or conductive layer 12 is additionally applied in a substantially all-over manner after having filled said open spaces 11.

Considering the fact that the conducting or conductive layer 10 formed in the method step according to FIG. 1h is usually made of the same material as is used to fill the hollow spaces 11 and to form the layer 12, the conducting or conductive layer 10 separately illustrated in FIG. 1h is no longer separately indicated in FIG. 1i, thus constituting a component of the material used to fill the holes or perforations 3 corresponding to the contacts 6, and also of the additional conductive layer 12.

The method steps according to FIGS. 1k and 1l depict further patterning steps for patterning a particularly multilayer printed circuit board, wherein it is apparent from the illustration according to FIG. 1k that the patterning of a resist 13 takes place corresponding to the subsequent patterning of, in particular, the layer or sheet 12 and/or the layer 1 coupled therewith. In the method step according to FIG. 11, it is indicated that partial regions of the layer 12 are again removed corresponding to the resist 13 applied in FIG. 1k, as is indicated by the offset or recessed regions 14 and 15 in FIG. 1l. FIG. 1l, moreover, indicates that the appropriate patterning of the further layer 8 may also be performed at the same time.

While substantially any material may be selected for the layer 1 supporting the electronic component 4 to be integrated, it is proposed, particularly to further pattern conducting or conductive elements, that already the layer 1 is made of a conducting or conductive material such that, in principle, a combined layer made of a material substantially identical with that of layers 1 and 12 is provided by the method step illustrated in FIG. 1i, as is indicated by a coherent layer in the subsequent method steps according to FIGS. 1k and 1l.

If the supporting layer 1 is made of a conducting or conductive material, it is moreover provided that the individual contacts or contact pads 6 are insulated relative to the conductive layer 1 by providing a suitable thickness or strength of the adhesive 5.

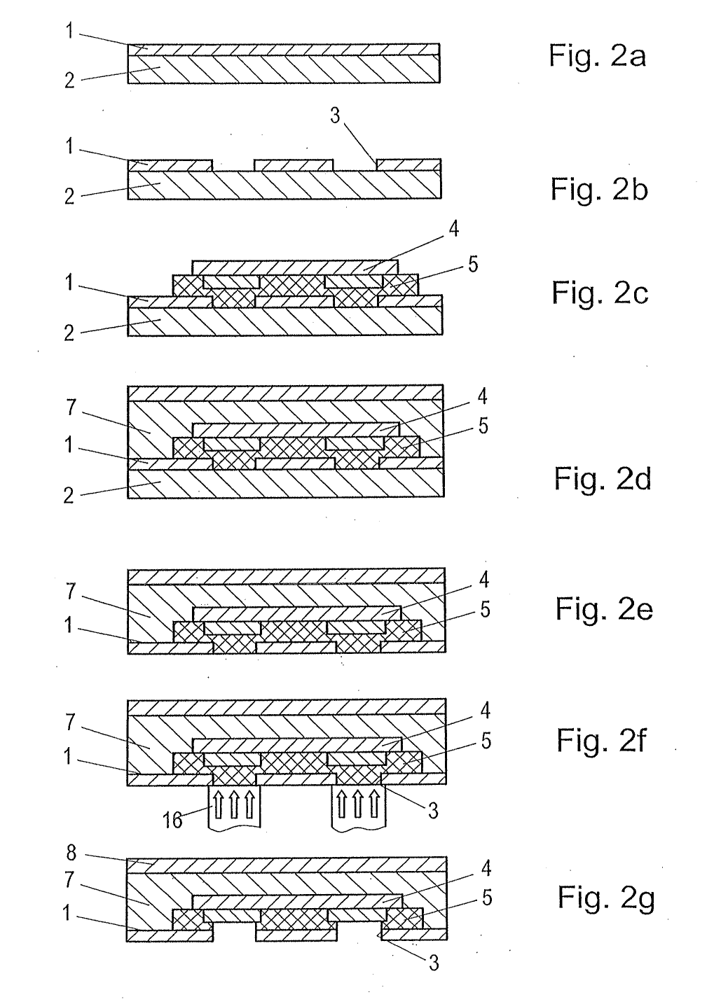

In the illustration according to FIG. 2, the reference numerals of FIG. 1 have been retained for identical elements or components, wherein it is apparent, when comparing the methods steps according to FIGS. 1a to 1g with the method steps according to FIGS. 2a to 2g, that the essential differences between the methods represented in FIGS. 1 and 2 reside, in particular, in the relative dimensions of the contacts 6 of the electronic component 4 to be integrated as well as in the thickness of the adhesive 5 used in the method according to FIG. 2.

A layer 1 is thus also provided on a carrier layer 2 in a first method step according to FIG. 2a of the method illustrated in FIG. 2, whereupon holes or perforations 3 are formed in the layer 1 in the subsequent method step according to FIG. 2b.

According to the method step of FIG. 2c, an adhesive 5 is applied in a layer thickness increased relative to the configuration of FIG. 1 to fix the electronic component 4 to be integrated, wherein also the contacts 6 have larger dimensions in the illustration according to FIG. 2 than in FIG. 1, this being taken into consideration by forming accordingly larger holes or perforations 3.

Similarly as with the embodiment according to FIG. 1, the method step according to FIG. 2d again comprises the sheathing of the electronic component 4 to be integrated, whereupon the carrier layer 2 is removed in the method step according to FIG. 2e.

To remove the adhesive 5 in the region of the holes or perforations 3, a laser beam denoted by 16 is again used in the method step represented in FIG. 2f. The laser beam 16 may be formed by a CO₂ laser similarly as in the embodiment according to FIG. 1f, wherein, particularly when taking into account the larger layer thickness of the adhesive 5, the following parameters according to Example 2 are used to completely remove the adhesive from the holes or perforations 3 within an accordingly short time:

### Example 2

### Thick Adhesive Layer (30-50 μm) and/or High Filler Content

Pulsed CO₂ laser
Power: 4 watts
Beam diameter: 280 μm
Pulse duration: 8 μs
Number of pulses: 13
Hole diameter: 120 μm

From the illustration of the method step according to FIG. 2g, it is again apparent that, after having used the laser beam 16 according to the method step of FIG. 2f, the holes or perforations 3 are completely freed from adhesive 5, again without having to fear a removal of adhesive 5 beyond the holes or perforations 3, due to the directed arrangement of the laser beam 16.

Similarly as with the embodiment illustrated in FIG. 1f, also the laser beam 16 has dimensions enlarged relative to the holes or perforations 3 in order to meet low demands in terms of aligning and registering the laser beam 16 relative to the holes 3, whereby the reliable removal of adhesive 5 from the holes 3 is achievable, thus altogether optimizing and reducing the process time.

Further method steps are taken according to the method steps depicted in FIGS. 1h to 1l in line with the preceding embodiment to form or apply the electrically conducting layer 10 for contacting the contacts 6 of the component 4 to be integrated and to arrange and/or form further elements of a particularly multilayer printed circuit board.

The method steps illustrated, in particular, in FIGS. 1h to 1l for patterning the particularly multilayer circuit board while embedding the electronic component 4 can, moreover, be performed in a manner deviating from the method steps represented in FIGS. 1h to 1l, particularly after the formation or production of the electrically conducting layer 10 for contacting the contacts 6 of the electronic component 4 to be integrated.

In particular, it is to be anticipated that, besides the patterning merely schematically indicated in FIGS. 1h to 1l, further layers or sheets are constructed and patterned to produce or further form a multilayer printed circuit board.

1. A method for integrating an electronic component into a printed circuit board, said method comprising the steps of
using a layer of a printed circuit board to support the electronic component;
forming holes or perforations corresponding to the contacts of the electronic component in the layer;
applying an adhesive to the layer supporting the electronic component;
fixing the electronic component to the layer with contacts oriented towards the layer and the holes or perforations;
removing adhesive possibly present in the region of the holes or perforations, especially by the application of a laser beam; and
forming an electroconductive layer for contacting the contacts of the electronic component on the surface or side of the layer facing away from the component,
wherein, in order to remove the adhesive (5) from the holes or perforations, a laser beam with dimensions or a diameter measuring more than the internal width of the holes or perforations is used.

2. The method according to claim 1, wherein the adhesive in the region of the holes or perforations is removed by a CO₂ laser beam.

3. The method according to claim 1, wherein a laser, particularly a pulsed CO₂ laser, having a power of 0.1 to 75 W, particularly 0.1 to 7 W, is used for a period or pulse length of 0.1 to 20 μs, to remove the adhesive from the holes or perforations.

4. The method according to claim 1, wherein the electronic component, once it has been fixed to the layer, is surrounded by an insulating material, particularly a prepreg sheet and/or a resin.

5. The method according to claim 1, wherein the layer for supporting the electronic component is applied to a carrier layer prior to forming the holes or perforations, which carrier layer is removed prior to removing the adhesive from the holes or perforations.

6. The method according to claim 1, wherein the layer for supporting the electronic component is formed by a conducting layer.

7. The method according to claim 1, wherein the electrically conducting layer for contacting the contacts of the electronic component is formed by chemically depositing an electrically conducting or conductive material, particularly copper, or by sputtering a metallic layer.

8. The method according to claim 1, wherein the electrically conducting layer is applied in a substantially all-over manner on the surface of the supporting layer, that faces away from the component.

9. The method according to claim 1, wherein, after having applied the electrically conducting layer, the holes or perforations are substantially completely filled with a conducting material corresponding to the contacts of the component, particularly by galvanically depositing a conducting material.

10. The method according to claim 9, wherein, after the holes have been filled with a conducting material, a substantially all-over layer of a conducting material is applied, particularly by galvanic depositing or plating.

11. The method according to claim 10, wherein the layer conducting substantially all over its surface is subsequently subjected to patterning, for instance laser patterning, photo-patterning or the like.

12. The method according to claim 1, wherein a thermally conducting or conductive adhesive is used to fix the component.
